(19) United States
(12) Patent Application Publication
(10) Pub. No.: US 2019/0223295 A1
(43) Pub. Date: Jul. 18, 2019

(54) FLEXIBLE ILLUMINATING MULTILAYER STRUCTURE

(71) Applicant: FLEXBRIGHT OY, Kangasala (FI)

(72) Inventors: Pekka MAKKONEN, Kangasala (FI); Kimmo KERÄNEN, Oulu (FI)

(73) Assignee: FLEXBRIGHT OY, Kangasala (FI)

(21) Appl. No.: 16/368,329

(22) Filed: Mar. 28, 2019

Related U.S. Application Data
(63) Continuation of application No. 15/529,253, filed on May 24, 2017, now abandoned.

(30) Foreign Application Priority Data
Nov. 24, 2014 (FI) 20146029

(51) Int. Cl. H05K 1/18; H05B 37/02; H05K 1/02; H01L 27/32; H05B 33/08

(52) U.S. Cl. CPC H05K 1/189; H05B 37/0245; H05K 1/0298; H01L 27/32; H05B 33/0842; F21Y 2115/10; H05K 2201/10106; H05K 2201/09709; H05K 2201/0108; H05K 1/0274; H05B 33/0863

(57) ABSTRACT

A flexible and illuminating multilayer structure wherein the flexible and illuminating multilayer structure has at least two flexible foils laminated together. Each foil has a flexible electrically conductive pattern layer and LED units distributed over the foil, the LED units being electrically contacted with the contact pattern. The LED units of a foil are positioned between positions of the LED units of the other foils. At least one foil of the multilayer structure, towards which at least one of the LED units is configured to radiate light, is transparent to the light. Brightness of the LED units is at least foil-specifically controllable with operational electric power fed to the foils through the contact pattern. The LED units of at least one foil are of a different tone or color or are controlled to output a different tone or color than the LED units of at least one other foil.

This is a Continuation of application Ser. No. 15/529,253 filed May 24, 2017, which in turn is a national phase of International Patent Application No. PCT/FI2015/050789 filed Nov. 12, 2015, which claims priority to Finnish Patent Application No. 20146029 filed Nov. 24, 2014. The disclosures of the prior applications are hereby incorporated by reference herein in their entireties.

### FIELD

The invention relates to a flexible illuminating multilayer structure.

### BACKGROUND

At the moment there are illuminating film-like structures which have LEDs as optical power sources. The LEDs are attached to the substrates of a polymer laminate the copper layer of which is patterned by etching. The polymer laminate is typically made of polyimide which has poor transparency particularly in visible light. Additionally, the polyimide laminate is expensive compared to low cost polymers such as PET, PEN and PC.

Thus, there is need for improvement in illuminating film-like structures.

### BRIEF DESCRIPTION

The present invention seeks to provide an improved flexible and illuminating structure. According to an aspect of the present invention, there is provided an illuminating multilayer structure as specified in claim 1.

According to another aspect of the present invention, there is provided an illuminating system in claim 6.

The invention provides improvement in illumination produced by an illuminating multilayer structure.

### LIST OF DRAWINGS

Example embodiments of the present invention are described below, by way of example only, with reference to the accompanying drawings, in which

FIG. 1 illustrates an example of a multi-layered flexible and illuminating multilayer structure;

FIG. 2 illustrates an example of an illuminating system; and

FIG. 3 illustrates an example of a processor and a memory.

### DESCRIPTION OF EMBODIMENTS

The following embodiments are only examples. Although the specification may refer to “an” embodiment in several locations, this does not necessarily mean that each such reference is to the same embodiment(s), or that the feature only applies to a single embodiment. Single features of different embodiments may also be combined to provide other embodiments. Furthermore, words “comprising” and “including” should be understood as not limiting the described embodiments to consist of only those features that have been mentioned and such embodiments may contain also features/structures that have not been specifically mentioned.

It should be noted that while Figures illustrate various embodiments, they are simplified and only show some structures and/or functional entities. The connections shown in the Figures may refer to electrical and/or physical connections. It is apparent to a person skilled in the art that the described apparatus may also comprise other functions and structures than those described in Figures and text. It should be appreciated that details of some functions, structures, power supply and the signalling are irrelevant to the actual invention. Therefore, they need not be discussed in more detail here.

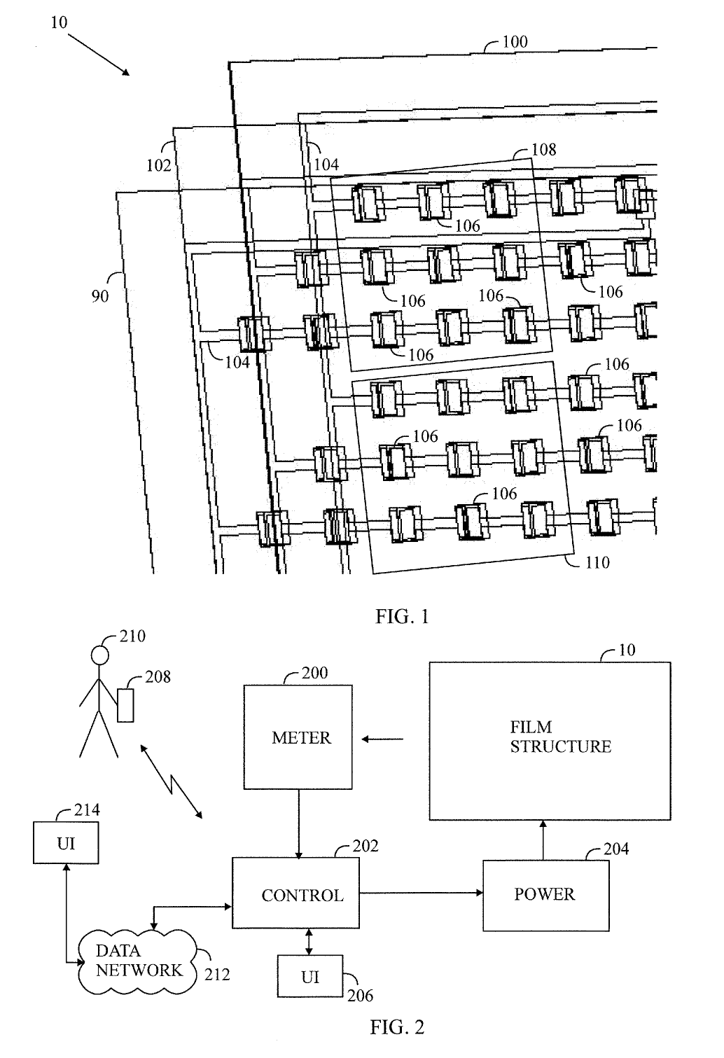

FIG. 1 shows an example of the flexible and illuminating multilayer structure 10. The multilayer structure comprises at least two flexible foils 100, 102 which may comprise polymer or paper for example. The flexible and/or stretchable substrate on which the multilayer structure is formed may comprise polymer such as elastomer, paper, flexible metal or the like. The foils 100, 102 are laminated together. The laminating may mean putting different foils and substrate one on the other and attaching them together by gluing, for example. Each of the foils 100, 102 has a flexible electrically conductive pattern layer 104. Additionally, a plurality of LED units 106 distributed over each of the foil 100, 102 (only a few of the LED units have been marked with the reference number). The abbreviation LED which is largely in use as such like a usual noun stands for Light Emitting Diode. The LEDs may comprise inorganic LEDs or organic LEDs. Any one of the LED unit emit light in at least one of the following: ultraviolet light band, visible light band and infrared light band. Ultraviolet and infrared optical bands enable functionalities different from those of visible light only.

The LED units 106 are electrically contacted with the electrically conductive pattern 104. The LED units 106 are at least foil-specifically controllable which means that LED units 106 of one foil may be separately controlled with respect to LED units 106 of any other foil. The electrically conductive pattern 104 may also enable an individual electric control of the LED units 106. The electrically conductive layer 104 may have been made by printing the pattern of the circuitry of the conductors and the contact areas for the LED units with at least one printable conductive ink.

The flexible and illuminating multilayer structure 10 may also comprise a flexible foil 90 which can be considered as a substrate of the multilayer structure 10. The polymer foils 90, 100, 102 may comprise plastic such as polyimide (PI), polyethylene terephthalate (PET), polyethylene naphthalate (PEN), polycarbonate (PC), liquid crystal polymer (LCP) or the like, for example.

The flexible and illuminating multilayer structure 10 also comprises a flexible and electrically conductive layer 104 which can be patterned for making conductors of an electric circuit which enable the operation of the illuminating multilayer structure 10.

The LED units 106 of a foil 100, 102 of the multilayer structure 10 are positioned between positions of the LED units 106 of the other foils of the multilayer structure 10. The LED units 106 which are in one foil 100, 102 have a LED unit free surrounding because the LED units are not in a physical contact with each other which results in a distance between any two LED units. By placing a LED unit of a foil in a gap between LED units of the other foils, the LED units 106 are not overlapping each other or shading each other's light.

At least one foil 100, 102 of the multilayer structure 10, towards which at least one of the LED units 106 radiates light, is transparent to the light. In this manner, the light of the LED units 106 can pass through the layers of the multilayer structure 10 and illuminate the environment.

Brightness of the LED units 106 of different foils 100, 102 is separately controllable with operational power fed through the foil 100, 102. The separate control of the LED units 106 in different foils 100, 102 is possible through the contact pattern 104 which allows the operational electric power to be fed individually to the foils 100, 102.

In an embodiment, brightness of each of the LED units 106 is separately controllable. The separate control of the LED units 106 is possible through the contact pattern 104 which allows the operational electric power to be fed individually to the LED units 106.

In an embodiment, the LED units 106 of at least one foil 100, 102 are of a different tone or color than the LED units 106 of at least one other foil 100, 102.

In an embodiment, the LED units 106 may comprise white light LEDs which have different tones/hues for controlling the overall tone/hue of the light emitted from the multilayer structure 10. In an embodiment, the used LEDs may provide tones which correspond to colour temperatures of 2700K, 3500K and 6000K. By using such LED units it is possible to adjust the tone from 2700K to 6000K. One foil may have LED units of colour temperatures of 2700K, another foil may have LED units of colour temperatures of 3500K and still another foil may have LED units of colour temperatures of 6000K. The colour temperature may also be higher, such as 6500K. In this manner, the tone of the illumination may be controlled by selecting a foil or foils the LED units of which are responsible for the illumination.

In an embodiment, the LED units 106 of one foil may comprise only red LEDs, another foil only green LEDs and still another foil blue LEDs. In this manner, the colour of the illumination may be controlled by selecting a foil or foils the LED units of which are responsible for the illumination.

In an embodiment, each of the LED units 106 may comprise at least one red LED, at least one green LED and at least one blue LED for controlling the brightness and the overall tone of the light emitted from multilayer structure 10.

In an embodiment, the LED units 106 of at least one foil 100, 102 may be controlled to output a different tone or color than the LED units 106 of at least one other foil 100, 102. For example, if all LED units 106 are white LEDs which comprise the at least one red LED, the at least one green LED and the at least one blue LED, one foil may be controlled to output red or reddish light and another foil may be controlled to output blue or bluish light. If there are more foils, a third foil may be controlled to output green or greenish light. In this manner, the colour of the illumination may be controlled by selecting a foil or foils the LED units of which are responsible for the illumination.

In an embodiment, light of at least a first part 108 of the LED units 106 may be directed to a different direction with respect to light of a second part 110 of the LED units 106 for controlling the spatial distribution of light radiated by the multilayer structure 10. In an embodiment, the first part 108 of the LED units 106 may comprise LED units of the first foil 100, and the second part 110 of the LED units 106 may comprise all LED units of the second foil 102. More generally, the Nth part 108 of the LED units 106 may comprise LED units of the Nth foil 100, where N is an integer larger than zero. The parts may have an equal or unequal number of LED units.

In an embodiment, the LED units 106 may comprise non-organic light emitting diode flip-chips. The flip-chips may reside in cavities of the foils 100, 102.

FIG. 2 illustrates an example of an illuminating system which comprises at least one multilayer structure 10. The system also comprises a controller 202 which adjusts at least one of the following: brightness, tone and radiation distribution of the multilayer structure 10. The system may also comprise a spectrum measuring unit 200 which measures the spectrum of the light radiated by the LED units 106.

In an embodiment, the system comprises a spectrum measuring unit 200 which may measure the spectrum of the light radiated by the LED units 106. The controller 202 may receive the measured information, and the controller 202 may then control the output of the at least one multilayer structure on the basis of the measured information such that a desired illumination is achieved. The controller 202 may compare the measured information to a target value of the illumination and adjust the control action on the basis of the comparison. This kind of comparison and generation of control action is per se known.

The controller 202 controls the LED units 106 separately on the basis of the foil 100, 102 in which the LED units 106 are located. That is, different foils 100, 102 may illuminate the environment differently. The difference of output of one foil 100, 102 with the LED units may be in intensity, tone, colour or direction of the illumination with respect to any other foil 100, 102. All foils 100, 102 with the LED units may also have the same illumination output if the LED units are capable of outputting a similar illumination and they are controlled to have a similar output.

The controller 202 controls the LED units 106 individually on the basis of the measured spectrum by the spectrum measuring unit 200. The spectrum measuring unit 200 may comprise a spectrometer. The spectrum measuring unit 200 and the multilayer structure 10 may be integrated together. The integration may mean that the spectrum measuring unit 200 and the multilayer structure 10 are physically and operationally combined. Thus the spectrum measuring unit 200 may be a part of the illuminating system.

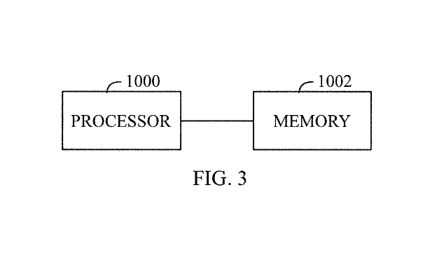

In an embodiment illustrated in FIG. 3, the controller 202 may comprise at least one processor 1000 and at least one memory 1002 including a computer program code. A computer program product may be embodied on a distribution medium readable by a computer and may comprise the program code which, when loaded into the at least one memory 1002 of the controller 202, causes the controller 202 to perform at least one of the step required by the measurement or the control.

The controller 202 may have in the memory 1002 or it may receive information about a target spectrum which the multilayer structure 10 is expected to provide to the environment. The controller 202 may control the operational power source 204 which feeds electric power to the LED units 106. The operational power source 204 may, according to the control command from the controller 202, feed electric power individually to each LED unit 106.

If a maximum operational electric power is fed to the LED units 106, they will illuminate the environment with the maximum intensity. By feeding an operational power lower than the maximum operational power, the multilayer structure 10 can be made to illuminate the environment with less intensity.

If a certain electric power is fed to LED units of a first tone and an electric power lower than said certain electric power to LED units of at least one different tone, the first tone will be emphasised in the overall tone of the multilayer structure 10. In this manner, the tone of the multilayer structure 10 can be controlled.

If a certain electric power is fed to red LEDs and no electric power to green and blue LEDs, the multilayer structure will illuminate the environment with red light. By controlling the intensity of the LED units of different colours, it is possible to control the illumination colour of the foil 10.

In an embodiment, the system has a user interface 206 which may feed the reference that a user inputs or selects to the controller 202 for adjusting brightness, tone or direction of illumination of the foil 10.

In an embodiment, a user 210 may have a remote controlling user interface 208 which may wirelessly feed the reference that a user inputs or selects to the controller 202 for adjusting brightness, tone or direction of illumination of the foil 10.

In an embodiment, the controller 202 may be coupled with a network 212 such as the Internet. A terminal 214 which is also coupled with the network 212 may feed the reference that a user inputs or selects to the controller 202 for adjusting brightness, tone or direction of illumination of the foil 10. The couplings between the terminal 214 and the network 212, and the controller 202 and the network 212 may be wired or wireless.

In order to decrease the thickness of the structure and improve the flexibility of the illuminating multilayer 10 the total thickness of the illumination multilayer structure 10 may be kept thin.

The flexible and illuminating multilayer structure 10 is a layered structure the thickness of which may be less than about 1 mm. The thickness may be about 0.1 mm or even less, for example. Although the thin multilayer is usually wanted, the multilayer may be made thicker such that the thickness is about 2 mm, for example.

The flexible and illuminating multilayer structure 10 may not only be thin but it may also have a small radius of curvature. The radius of curvature may be less than 10 mm, for example. The radius of curvature may go down to about 1 mm, for example. The surface on which the flexible and illuminating multilayer 10 is placed may be planar, curved or even double curved.

By using inorganic light emitting chips the brightness of each illuminating foil 100, 102 may be over 1000 cd/m² or even more than 5000 cd/m². By having three illuminating foils, the adjustment range is correspondingly multiplied by three 0 to 3000 cd/m² or even to 15 000 cd/m².

In an embodiment, the illumination of the multilayer structure 10 may be directed to a hemisphere by laminating or otherwise attaching a reflective layer on one side of the multilayer structure 10.

The flexible illuminating multilayer structure 10 may be manufactured using a roll-to-roll (R2R) method.

All in all, this solution solves the problem of color and/or hue tuning implementation principle and structure for thin and flexible large area lighting system. A large area may mean hundreds of square centimeters. The area may be 3600 cm² or larger, for example. As a contrast to hue lamps of the prior art, the existing hue lamps are typically based on RGB led modules, which are packaged inside rigid and bulky lamp structures. Those lamp structures bear similarity to point sources and implementation of thin, flexible and large-area lighting solution using those is technically impossible.

As to application of the flexible, large-area illuminating multilayer structure, one or more foils 10 may be applied inside houses for creating different illuminations. The illuminations may be changed according to moods, times of a day, and seasons. The illumination may be bluish in the morning but reddish in the evening. During dark seasons such as autumn and winter a person with a seasonal affective disorder (SAD) may like to have a very bright illumination inside the house. Actually, the brightness of the illumination may be controlled according the best recommendations of professionals or according to a personal need or desire. A ready-made control algorithm may be stored or a control program may be programmed and stored in the controller 202.

In an embodiment, one or more foils 10 may be applied in green houses. Different flora may be controlled to have unique and suitable illumination for their needs. Additionally, the illumination may be controlled to vary according to the phase of growth of plants.

The foil 10 may also find use in traffic signs, illumination of register plates of vehicles and illumination of signs, guideposts and billboards.

In an embodiment, the aspects of the invention may be realized as software and a computer or a set of computers of the processing system or a web service system connected to the Internet.

The computer programs may be in source code form, object code form, or in some intermediate form, and it may be stored in some sort of carrier, which may be any physical entity or device capable of carrying the program. Such carriers include a record medium, computer memory, read-only memory, and software distribution package, for example. Depending on the processing power needed, the computer program may be executed in a single electronic digital controller or it may be distributed amongst a number of controllers.

It will be obvious to a person skilled in the art that, as technology advances, the inventive concept can be implemented in various ways. The invention and its embodiments are not limited to the example embodiments described above but may vary within the scope of the claims.

1. A flexible and illuminating multilayer structure wherein the flexible and illuminating multilayer structure comprises:
at least two flexible foils laminated together using glue, wherein
each of the foils has a flexible electrically conductive pattern layer and a plurality of light emitting diodes distributed over the foil, the light emitting diodes being electrically contacted with the flexible electrically conductive pattern layer;
the light emitting diodes of a foil of the multilayer structure are positioned between positions of the light emitting diodes of the other foils of the multilayer structure;
at least one foil of the multilayer structure, towards which at least one of the light emitting diodes is configured to radiate light, is transparent to the light;
brightness of each of the light emitting diodes radiating light is separately controllable by individual electric control through the flexible electrically conductive pattern layer and different foils are configured to be separately controllable on the basis of operational electric power fed to the foils through the flexible electrically conductive pattern layer;
direction of illumination of the different foils is configured to be controllable by user inputs or selections to a controller for adjusting direction of illumination and controlling a spatial distribution of light radiated by the multilayer structure from a first spatial distribution of light output by the multilayer structure to a second spatial distribution of light output by the multilayer structure; and
the light emitting diodes of at least one foil are of a different tone or color or are controlled to output a different tone or color than the light emitting diodes of at least one other foil.

2. The multilayer structure of claim 1, wherein brightness of each of the light emitting diodes is configured to be individually controllable through the flexible electrically conductive pattern layer.

3. The multilayer structure of claim 1, wherein the light emitting diodes comprise white light emitting diodes which have different tones for controlling the tone of the multilayer structure.

4. The multilayer structure of claim 1, wherein each of the Light emitting diodes comprise at least one red light emitting diode, at least one green light emitting diode and at least one blue light emitting diode for controlling the brightness and the tone of the multilayer structure.

5. The multilayer structure of claim 1, wherein light of at least a first part of the light emitting diodes is directed to a different direction with respect to light of a second part of the light emitting diodes for controlling the spatial distribution of light radiated by the multilayer structure.

6. An illuminating system wherein the system comprises at least one multilayer structure of claim 1 and the controller configured to adjust at least one of the following: brightness, tone and radiation distribution of the multilayer structure, by controlling the light emitting diodes separately on the basis of the foil in which the light emitting diodes are located.

7. The system of claim 6, wherein the system comprises an operational electric power source which is configured to feed operational electric power to the light emitting diodes individually, and the controller is configured to control the operational electric power source to feed operational power individually to the light emitting diodes.

8. The system of claim 6, wherein the system comprises a spectrometer configured to measure the spectrum of the light radiated by the light emitting diodes, the controller is configured to receive the measured information and control the output of the at least one multilayer structure on the basis of the measured information.

9. The system as claimed in claim 6, wherein the controller comprises at least one processor; and at least one memory including a computer program code, wherein the at least one memory and the computer program code are configured, with the at least one processor, to cause the controller at least to perform
adjusting at least one of the following: brightness, tone and radiation distribution of the multilayer structure, by controlling the light emitting diodes of different foils.

10. An illuminating system comprising:
at least one multilayer structure of claim 1; and
the controller configured to receive inputs from a user to adjust the spatial distribution of light for illuminating an environment.

11. The multilayer structure of claim 1, wherein the first spatial distribution illuminates an environment differently than the second spatial distribution illuminates the environment.
